(19) United States
(12) Patent Application Publication
(10) Pub. No.: US 2026/0038570 A1
(43) Pub. Date: Feb. 5, 2026

(54) CONTROL CIRCUIT AND SEMICONDUCTOR MEMORY DEVICE

(71) Applicant: Winbond Electronics Corp., Taichung City (TW)

(72) Inventor: Shinya OKUNO, Yokohama (JP)

(73) Assignee: Winbond Electronics Corp., Taichung City (TW)

(21) Appl. No.: 19/252,990

(22) Filed: Jun. 27, 2025

(30) Foreign Application Priority Data
Jul. 30, 2024 (JP) 2024-123179

(51) Int. Cl. G11C 11/4076; H03K 3/037; H03K 19/20

(52) U.S. Cl. CPC G11C 11/4076; H03K 3/037; H03K 19/20

(57) ABSTRACT

The control circuit of this invention includes: a control unit, configured to generate a control signal indicating a delay amount; a delay line unit, configured to receive an input clock signal, and based on the control signal, perform a delay operation to generate an output clock signal; and a temporary delay amount selection unit configured to receive the output clock signal, generates a plurality of temporary delay signals that delay the output clock signal by a respective plurality of different temporary delay amounts, then performs a selection operation to select whichever of the temporary delay signals is closest in phase to the input clock signal, and outputs an output signal that indicates the temporary delay amount of the selected temporary delay signal. The control unit sets the delay amount according to the output signal indicating the temporary delay amount.

### CROSS REFERENCE TO RELATED APPLICATIONS

This application claims priority of Japan Patent Application No. 2024-123179, filed on Jul. 30, 2024, the entirety of which is incorporated by reference herein.

### BACKGROUND OF THE INVENTION

### Field of the Invention

The present invention relates to a control circuit and a semiconductor memory device.

### Description of the Related Art

Dynamic random access memory (DRAM) is a kind of semiconductor memory device storing charges through capacitors to memorize data. When the power supply stops, the memorized date will be lost, so this memory belongs to a type of memory called volatility memory. A phase synchronization circuit is disposed in the DRAM (specifically, a delay locked loop (DLL) circuit). The DRAM uses the DLL circuit to generate an internal clock signal for outputting data signals in synchronization with an input clock signal input from the outside (e.g., refer to Patent 1: U.S. Patent Publication No. 2023/308103). During the delay operation of the DLL circuit, a feedback signal will be generated from the output signal of the delay line unit, and be compared with the input clock signal to achieve synchronization.

In this DLL circuit, during the delay operation, the feedback signal will be compared with the input clock signal, and the input clock signal will be delayed from performing the delay operation. Specifically, the delay amount added to the input clock signal is gradually changed to achieve the proper delay amount. However, the feedback signal will generate jitter. Thus, when the delay amount is gradually changed multiple times, the impact of jitter increases, and causes the overflow or underflow issue.

### BRIEF SUMMARY OF THE INVENTION

The present disclosure provides a control circuit and a semiconductor memory device that can suppress the impact of jitter and the occurrence of overflow or underflow.

A control circuit of the present disclosure comprises a control unit, a delay line unit, and a temporary delay amount selection unit. The control unit generates a control signal indicating a delay amount. The delay line unit is configured to receive an input clock signal. Based on the control signal the delay line unit is configured to perform a delay operation to generate an output clock signal. The temporary delay amount selection unit is configured to receive the output clock signal. The temporary delay amount selection unit is configured to generate a plurality of temporary delay signals that delay the output clock signal by a respective plurality of different temporary delay amounts. The temporary delay amount selection unit then performs a selection to select whichever one of the temporary delay signals whose phase is closest to a phase of the input clock signal. The temporary delay amount selection unit is configured to output an output signal that indicates the temporary delay amount of the temporary selected delay signal. The control unit sets the delay amount according to the output signal that indicates the temporary delay amount.

In the present disclosure, since the plurality of temporary delay signals can be generated by the temporary delay amount selection unit to perform the selection operation that selects, from among all the temporary delay signals, the temporary delay signal whose temporary delay amount is closest to the required delay amount. Thus, the delay amount can be set in one delay operation without the need to perform delay operations multiple times. In this way, the impact of jitter and the occurrence of overflow or underflow can be suppressed.

A semiconductor memory device of the present disclosure comprises the control circuit described above. Since the control circuit described above is provided, the impact of jitter and the occurrence of overflow or underflow can be suppressed. Thus, the semiconductor memory device of the present disclosure can operate satisfactorily.

The impact of jitter and the occurrence of overflow or underflow can be suppressed according to the control circuit and the semiconductor memory device of the present disclosure.

### BRIEF DESCRIPTION OF THE DRAWINGS

The present invention can be more fully understood by reading the subsequent detailed description and examples with references made to the accompanying drawings, wherein:

FIG. 1 is a block diagram of the exemplary structure of the control circuit in the first embodiment of the present disclosure;

FIG. 2 is a structural diagram of the temporary delay amount generation unit in the first embodiment of the present disclosure;

FIG. 3 schematically shows a graph of the relationship between the delay feedback signal and the input clock signal;

FIG. 4 is a structural diagram of the temporary delay amount generation unit in the second embodiment of the present disclosure;

FIG. 5 schematically shows a graph of the relationship between the delay feedback signal and the input clock signal; and

FIG. 6 is a diagram of the varied example of the second phase detection unit.

### DETAILED DESCRIPTION OF THE INVENTION

### The Embodiments for Implementing the Present Disclosure

The following description is made for the purpose of illustrating the general principles of the invention and should not be taken in a limiting sense. The scope of the invention is best determined by reference to the appended claims.

The control circuit and the semiconductor memory device in the embodiments of the present disclosure are described in detail below, with reference to the accompanying drawings. However, these embodiments are only examples, and the present disclosure is not limited thereto.

### The First Embodiment

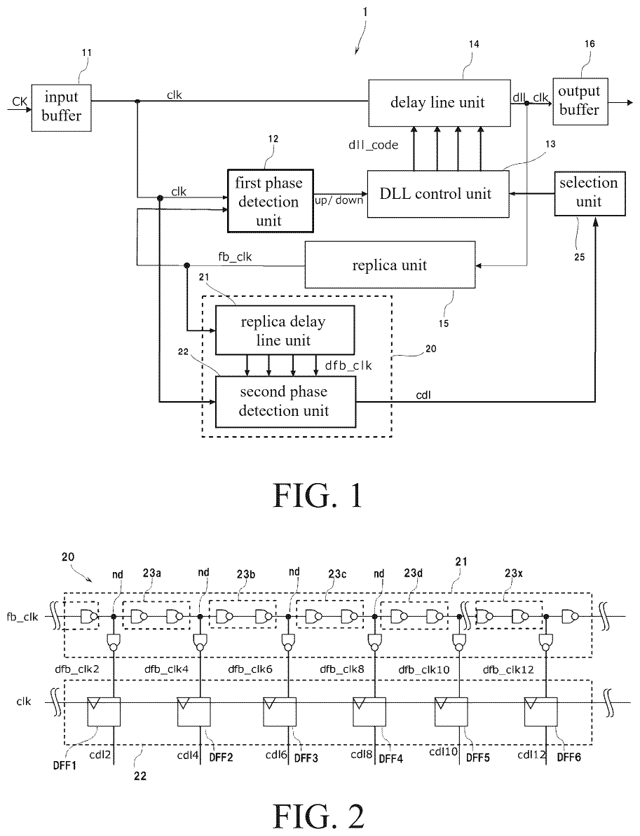

FIG. 1 shows an exemplary structure of the control circuit in the embodiment of the present disclosure. In the present embodiment, a control circuit 1 is disposed in a semiconductor memory device, for example, the DRAM, or the like. Furthermore, to simplify the illustration, the structures known in the art (e.g., command decoder, memory unit array, input/output interface unit, or the like) commonly disposed in semiconductor memory devices, such as DRAM, or the like, are not shown.

The control circuit 1 comprises an input buffer 11, a first phase detection unit 12, a DLL control unit 13, a delay line unit 14, a replica unit 15, an output buffer 16, a temporary delay amount generation unit 20, and a selection unit 25. If there is a need for distinguishing the same constituent elements based on their locations, or the like, the letters or numbers will be added after the constituent elements to distinguish them. Furthermore, in the present embodiment, the DLL control unit 13 is an example of the “control means” of the present disclosure, the temporary delay amount generation unit 20 is an example of the “temporary delay amount generation means” of the present disclosure, and the selection unit 25 is an example of the “selecting means” of the present disclosure.

The input buffer 11 buffers the external clock signal CK input to the input buffer 11, and generates an input clock signal clk. The input clock signal clk is sent to the delay line unit 14 and the first phase detection unit 12. The delay line unit 14 generates a delay signal (an output clock signal) dll_clk that delays the input clock signal, and sends it to the output buffer 16 and the replica unit 15. The replica unit 15 outputs the delay signal dll_clk generated by the delay line unit 14 to the first phase detection unit 12, as a feedback signal fb_clk.

The first detection unit 12 detects a phase difference between the input clock signal clk and the feedback signal fb_clk. Specifically, when the input clock signal clk and the feedback signal fb_clk are input to the first phase detection unit 12, the first phase detection unit 12 generates a phase signal up/down indicating the phase advance or delay (phase difference) of the feedback signal fb_clk with respect to the input clock signal clk, and inputs the phase signal up/down to the DLL control unit 13.

The DLL control unit 13 determines a delay amount and generates a control signal dll_code based on the delay amount. Specifically, based on the phase signal up/down and a state signal cdl described below, the DLL control unit 13 generates a signal indicating the delay amount in a locking operation (an example of the “delay operations” of the present disclosure); that is, from a plurality of control signals dll_code made of multi-bits, and outputs it. The output control signal dll_code is input to the delay line unit 14.

The delay line unit 14 is a variable delay unit performing a locking operation described below: when the control signal dll_code indicating the delay amount set by the DLL control unit 13 is input, the input clock signal clk is delayed according to the control signal dll_code, and then the delay line unit 14 generates the delay signal (the output clock signal) dll_clk and outputs the delay signal (the output clock signal) dll_clk to the output buffer 16.

The delay amount refers to how much the input clock signal clk is delayed by the delay signal dll_clk during the delay operation described herein. A delay time tDLL set based on the delay amount can be expressed as the following equation:

$$tDLL = X * CDL + Y * FDL$$

(CDL indicates the coarse delay line)
(FDL indicates the fine delay line)

Therefore, the delay time is determined by the X value and Y value set by the DLL control unit 13, and the X value and Y value indicate the activation degree of the CDL and FDL, respectively.

The control signal dll_code comprises both the X value and Y value. The X value usually refers to a value that is conventionally set by the DLL control unit 13 by changing the delay multiple times. In other words, to set the delay amount, the DLL control unit 13 starts to temporarily set the X value temporarily from the initial delay amount, generates the control signal dll_code, and detects the phase difference between the input clock signal clk and the feedback signal fb_clk based on the phase signal up/down from the first phase detection unit 12. If the phase difference is large, the X value will be increased, and the control signal dll_code will be generated again to set the best X value (setting operation) through the feedback control that gradually approaches the best delay amount. Then, after obtaining the X value, the Y value is set and fine-tuned based on the phase signal up/down of the first phase detection unit 12 to set the best control signal dll_code (Y value setting operation).

In contrast, when the delay operation starts, the conventional initial operation is a setting operation. However, in the present embodiment, the temporary delay amount selection unit is set to stop the input of the phase signal up/down from the first phase detection unit 12, and to start the selection operation performed by the temporary delay amount selection unit. The temporary delay amount selection unit generates a plurality of replica delay signals (the temporary delay signals) dfb_clk, by delaying the feedback signal fb_clk (having the same phase as the delay signal (the output clock signal) dll_clk), by a respective plurality of different temporary delay amounts. Then, the temporary delay amount selection unit performs the selection operation to select, from among all the replica delay signals dfb_clk, whichever replica delay signal dfb_clk exhibits the smallest phase difference with respect to the input clock signal clk, and sets the delay amount according to the temporary delay amount of the selected replica delay signal dfb_clk. The temporary delay amount indicates how much the feedback signal fb_clk is delayed by the replica delay signal dfb_clk in the replica delay line unit 12 described herein. However, it is not used to actually preform the delay operation in the delay line unit 14.

In the present embodiment, the replica delay signals (temporary delay signals) dfb_clk are generated, and the delay amount is predicted instead of being set in the setting operation. The control signals dll_code with different delay amount are generated by the DLL control unit 13 multiple times in an operation that is performed using the conventional method. Therefore, the best delay amount can be set using one selection operation.

The temporary delay amount selection unit comprises: the temporary delay amount generation unit 20 disposed at the back end of the replica unit 15 and the front end of the first phase detection unit 12, and the selection unit 25 disposed at the back end of the temporary delay amount generation unit 20 and the front end of the DLL control unit 13. The feedback signal fb_clk and the input clock signal clk are input to the temporary delay amount generation unit 20. The temporary delay amount generation unit 20 comprises a replica delay line unit 21 and a second phase detection unit 22.

The feedback signal fb_clk is input to the replica delay line unit 21. The replica delay line unit 21 generates the replica delay signals dfb_clk that delay the input feedback signal fb_clk by different amounts respectively, and sends them to the second phase detection unit 22 respectively. The replica delay signals dfb_clk and the input clock signal clk are input to the second phase detection unit 22. The phase difference between each replica delay signal dfb_clk and the input clock signal clk is detected in the second phase detection unit 22. The second phase detection unit 22 outputs the state signals cdl indicating the phase difference to the selection unit 25, and the selection unit 25 selects the best one from among these state signals cdl.

FIG. 2 illustrates the specific structure of the replica delay line unit 21 and the second phase detection unit 22. The replica delay line unit 21 mimics the structure of the delay line unit 14. In other words, it has the same structure as the delay line unit 14 and is made of a plurality of NAND gates connected in series. A delay element 23 is made of two adjacent NAND gates as a group. The delay elements 23 are also connected in series. There are a plurality of series connections from the delay element 23a to the delay element 23x. Each replica delay signal dfb_clk introduced from the node nd between the delay elements 23 has a different temporary delay amount according to the number of delay elements 23 passed by the feedback signal fb_clk. The replica delay signal dfb_clk which is closer to the temporary delay amount of the input side is smaller. When the feedback signal fb_clk passes a delay element 23, the temporary delay amount of the replica delay signal dfb_clk becomes larger.

For example, the replica delay signal dfb_clk6 output from the delay element 23b neighboring the delay element 23a is delayed by a delay amount of one delay element 23 more than the replica delay signal dfb_clk4 output from the delay element 23a. In this case, the temporary delay amount that can be set by the delay element 23 in the replica delay line unit 21 should be set to be longer than one clock cycle (1tCK). This setting can ensure that even when the delay amount is large, the temporary delay amount can also be set sufficiently and stably. Furthermore, another NAND gate is disposed between the node nd and the second phase detection unit 22, and each replica delay signal dfb_clk is output to the second phase detection unit 22 through this NAND gate.

The second detection unit 22 is made of a plurality of D-type flip-flop circuits DFF, and the input clock signal clk and each replica delay signal dfb_clk are input to each D-type flip-flop circuit DFF. For example, the input clock signal clk and the replica delay signal dfb_clk2 are input to the D-type flip-flop circuit DFF1, and the input clock signal and the replica delay signal dfb_clk4 are input to the D-type flip-flop circuit DFF2. Each D-type flip-flop circuit DFF detects whether the replica delay signal dfb_clk is high level or low level at the time point of the clock rising of the input clock signal clk, and outputs the state signals cdl at once. The state signals cdl are output to the selection unit 25 respectively.

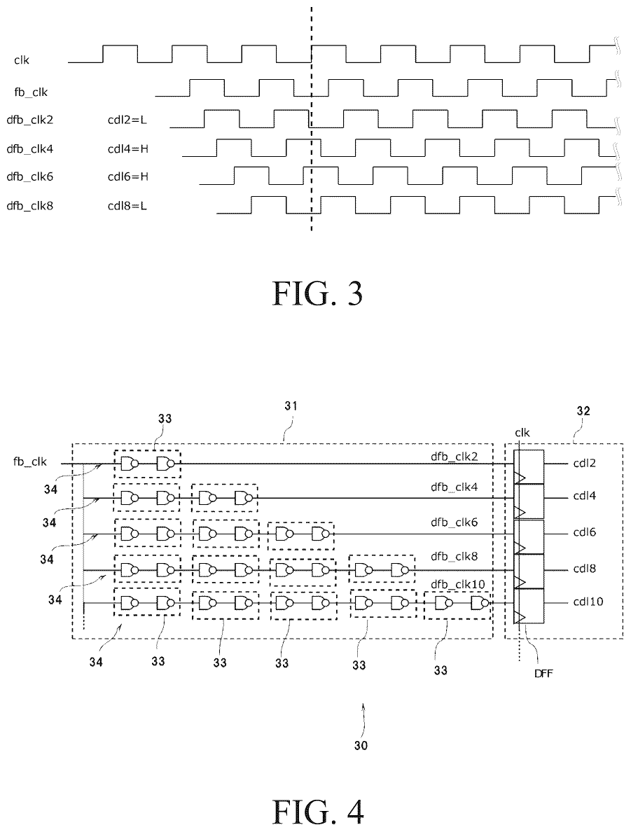

The specific operation of the replica delay line unit 21 and the second phase detection unit 22 will be illustrated with refer to FIG. 3. In FIG. 3, the input signal clk, the feedback signal fb_clk, and the replica delay signals dfb_clk2˜dfb_clk8 generated by the replica delay line unit 21 are arranged and displayed. The replica delay signals dfb_clk2˜dfb_clk8 are respectively delayed by different temporary delay amount with respect to the feedback signal fb_clk, in accordance with the delay element 23, as described above. In this case, the logic states of each replica delay signal dfb_clk2˜dfb_clk8 are low level, high level, high level, low level respectively at the rising time point of the input clock signal clk (the rising edge is indicated by the dotted line in FIG. 3). Therefore, the state signals cdl1˜cd18 output from each D-type flip-flop circuits DFF1˜4 indicate “L”, “H”, “H”, “L” respectively. These state signals cdl are input to the selection unit 25 all at once.

Then, the selection unit 25 sequentially selects, from among all the status signals cdl input at once, a status signal cdl whose logic state changes from a high level to a low level, wherein the status signals are selected sequentially in order of increasing temporary delay amount, beginning with the status signal cdl associated with the smallest temporary delay amount. That is, when a state signal cdlx indicates a high level and the next state signal cdly indicates a low level, the control signal dll_code will be formed based on the state signal cdlx. In FIG. 3, the state signals cdl1˜cd18 are “L”, “H”, “H”, “L” respectively. The logic state change occurs between the state signal cdl6 and state signal cdl8, and the status signal cdlx that at the time the high level drops to the low level is the status signal cd16. When the logic state changes, it indicates that the phase between the input clock signal clk and the replica delay signal dfb_clk is reversed forward or backward, so the phase difference between the input clock signal clk and the replica delay signal dfb_clk is smaller. Therefore, the selection unit 25 selects any one of the state signals cdlx, cdly before and after the logic state change (i.e., in the present embodiment, the state signal cdlx before the logic state change) as the selected temporary delay amount. Thus, the DLL control unit 13 can set a proper delay amount.

The selection unit 25 inputs the selected state signal cdl to the DLL control unit 13. Then, the DLL control unit 13 sets the X values according to the temporary delay amount indicated by the selected state signal cdl.

In the DLL control unit 13, during the selection operation that is performed by the temporary delay amount selection unit, the phase signal up/down from the first phase detection unit 12 will not be input, and the conventional setting operation will not be performed. Actually, the delay operation of the delay line unit 14 stops (that is, the update of the control signal dll_code is suspended). Then, when the selection operation ends, the replica delay line unit 21 and the second phase detection unit 22 stop, and the input of the phase signal up/down from the first phase detection unit 12 recovers to perform the setting operation of the Y value. Thus, the control signal dll_code of the DLL control unit 13 is updated, and is input to the delay line unit 14 so that the previously stopped delay operation can be performed.

In the present embodiment, the phase signal up/down of the first phase detection unit 12 will not be output to the delay line unit 14 during the selection operation that selects the replica delay signal dfb_clk that is closest in phase to the input clock signal through the temporary delay amount selection unit that generates the replica delay signals dfb_clk and detects these phases at once, so the update of the control signal dll_code of the delay line unit 14 stops. When the selection operation is completed, the control signal can be updated to a proper value at once. Thus, compared with the conventional case that gradually adjusts the delay amount by changing the control signal dll_code multiple times, the impact of jitter can be largely suppressed, and the occurrence of underflow and overflow can be suppressed, too.

Furthermore, in the present embodiment, since the temporary delay amount generation unit 20 is disposed, the feedback signal fb_clk output from the replica unit 15 and the input clock signal clk can be used to perform the phase detection, and their structures are simple. In addition, regardless of the structure of the delay line unit 14, as long as the temporary delay amount generation unit 20 is disposed at the back end of the replica unit 15 as in the present embodiment, a better delay amount detection can be performed at once.

### The Second Embodiment

In the present embodiment, a temporary delay amount generation unit 30 having a different structure from the temporary delay amount generation unit 20 of the first embodiment is included. As shown in FIG. 4, the temporary delay amount generation unit 30 also comprises a replica delay line unit 31 and a phase detection unit 32. Furthermore, in the second embodiment, the structure of the control circuit 1 is the same except for the temporary delay amount generation unit 30, and is therefore omitted.

The replica delay unit 31 is formed by connecting a plurality of delay element columns 34 made of delay elements 33 in parallel. Each delay element column 34 is made of a different number of delay elements 33 each connected in series, and each delay element 33 is made of two NAND gates connected in series. The outputs of each delay element column 34 are the replica delay signals dfb_clk as same as the first embodiment, and each of them has different temporary delay amount according to the number of delay elements 33. The replica delay signal dfb_clk is output to each D-type flip-flop circuit DFF of the phase detection unit 32. The input clock signal clk is also input to the D-type flip-flop circuits DFF. Then, each D-type flip-flop circuit DFF outputs the state signal cdl indicating whether the replica delay signal dfb_clk is a high level or a low level at the rising time point of the input clock signal clk.

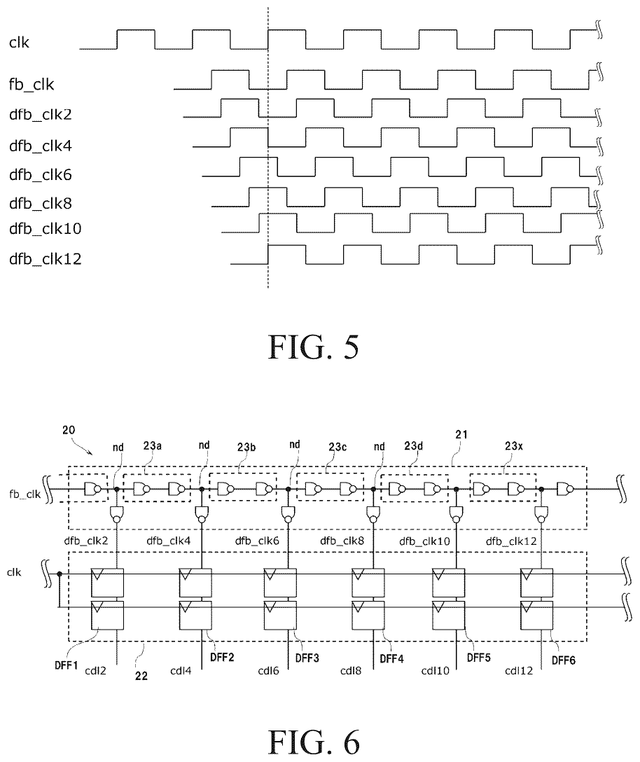

In this case, the state signal cdls indicating whether the replica delay signals dfb_clk is a high level or a low level can also be output at the rising time point (rising edge) of the input clock signal clk at once. As shown in FIG. 5, in the present embodiment, the logic state of the state signal cdl10 is a high level, and the logic state of the state signal cd112 is a low level. Thus, the selection unit 25 selects the state signal cdl10, selects the temporary delay amount of the state signal cd110, and inputs this temporary delay amount to the DLL control unit 13.

As shown in the first embodiment and second embodiment, the structures of the temporary delay amount generation unit 20, 30 are not limited, as long as the replica delay signals can be set at the same time, and the phase difference between the input clock signal and these many delay signals can be detected at once.

### The Variation Embodiment

In the above embodiments, although the delay elements are all NAND gates, they are not limited herein. Other delay means can be used to form them. That is, it is preferable that the delay line unit 14 and the replica delay line units 21, 31 respectively have the same constituent elements. Thus, if the delay line unit 14 is made of the NAND gates, it is preferable that the replica delay line units 21, 31 are made of the NAND gates. However, if the delay line unit 14 is made of the flip-flops, it is preferable that the replica delay line units 21, 31 are made of the flip-flops. Furthermore, although the selection unit 25 is disposed at the front end (outside) of the DLL control unit 13 in the present embodiment, it is not limited herein. For example, the selection unit 25 can be disposed inside the DLL control unit 13. For example, the selection unit 25 can be also disposed at the second phase detection unit 22 such that the state signal cdl selected from the selection unit 25 is input to the DLL control unit 13.

Furthermore, the second phase detection unit 22 can be configured as a synchronizer by connecting two stages as shown in FIG. 6. The logic state can be determined more stably. In addition, in the embodiment above, when changing from a high level to a low one, the delay amount is set according to a state signal cdl that is a high level, but it can also be set according to the next state signal cdl that is a low level.

In the above embodiment, although the semiconductor memory device, which is a DRAM, having a control circuit is illustrated as an example, the present disclosure is not limited herein. For example, the semiconductor memory device can be a static random access memory (SRAM), flash memory or other semiconductor memory device.

The embodiments and variation embodiments illustrated above are described to make the present disclosure easier to understand, and are not intended to limit the present disclosure. Thus, the elements disclosed in the above embodiments and variation embodiments also include all design modification and the equivalents within the technical scope of the present disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A control circuit, comprising:
a control unit, configured to generate a control signal indicating a delay amount;
a delay line unit, configured to receive an input clock signal, and based on the control signal, perform a delay operation to generate an output clock signal; and
a temporary delay amount selection unit, configured to receive the output clock signal, generate a plurality of temporary delay signals that delay the output clock signal by a respective plurality of different temporary delay amounts, perform a selection operation to select the temporary delay signal having a phase closest to a phase of the input clock signal from the temporary delay signals, and output an output signal indicating the temporary delay amount of the selected temporary delay signal;
wherein the control unit sets the delay amount according to the output signal indicating the temporary delay amount.

2. The control circuit as claimed in claim 1, wherein while the temporary delay amount selection unit performs the selection operation, the delay operation of the delay line unit is suspended.

3. The control circuit as claimed in claim 1, wherein the temporary delay amount selection unit comprises:
a temporary delay amount generation unit, configured to generate the plurality of temporary delay signals that delay the output clock signal by the respective plurality of different temporary delay amounts; and
a selection unit, configured to select the temporary delay signal having the temporary delay amount that is closest to the delay amount from the temporary delay signals, and output the output signal indicating the temporary delay amount of the selected temporary delay signal.

4. The control circuit as claimed in claim 3, wherein the temporary delay amount generation unit comprises:
a replica delay line unit, configured to receive a feedback signal in a same phase with the output clock signal; and
a phase detection unit, configured to receive the input clock signal;
wherein the feedback signal is delayed from generating the temporary delay signals having the temporary delay amount differently in the replica delay line unit;
the plurality of temporary delay signals are input to the phase detection unit.

5. The control circuit as claimed in claim 4, wherein the selection unit is disposed at the control unit or the phase detection unit.

6. The control circuit as claimed in claim 4, further comprising a replica unit configured to receive the output clock signal from the delay line unit, and output the feedback signal to the replica delay line unit.

7. The control circuit as claimed in claim 4, wherein the phase detection unit detects logic states of each of the temporary delay signal respectively according to the input clock signal, generates state signals as signals indicating the temporary delay amount, and inputs the state signals to the selection unit.

8. The control circuit as claimed in claim 7, wherein when the selection unit compares the temporary delay amount of the state signals in ascending order, and the logic state between one of the temporary delay signals and the next one of the temporary delay signals varies, the temporary delay amount is set by the state signal of the one of the temporary delay signals or the next one of the temporary delay signals.

9. The control circuit as claimed in claim 8, wherein a variation of the logic state is that the logic state of the one of the temporary delay signals is a high level, and the logic state of the next one of the temporary delay signals is a low level.

10. The control circuit as claimed in claim 3, wherein a maximum temporary delay amount generatable by the temporary delay amount generation unit is larger than one clock cycle.

11. The control circuit as claimed in claim 4, wherein the replica delay line unit and the delay line unit have the same structure.

12. The control circuit as claimed in claim 4, wherein the replica delay line unit is made of a plurality of delay elements connected in series that delay the input clock signal by a predetermined amount.

13. The control circuit as claimed in claim 4, wherein the replica delay line unit is made of columns of delay elements disposed in parallel, and the columns of the delay elements are made of a plurality of delay elements connected in series.

14. The control circuit as claimed in claim 4, wherein the phase detection unit includes a plurality of D-type flip-flop circuits.

15. The control circuit as claimed in claim 4, wherein the phase detection unit is made of a synchronizer formed by a plurality of D-type flip-flop circuits in two stages.

16. The control circuit as claimed in claim 12, wherein the delay elements are made of NAND gates.

17. A semiconductor memory device, comprising a control circuit as claimed in claim 1.

18. The semiconductor memory device as claimed in claim 17, wherein the semiconductor memory device is a dynamic random access memory.
